(19) United States
(12) Patent Application Publication
(10) Pub. No.: US 2006/0077492 A1
(43) Pub. Date: Apr. 13, 2006

(54) Method and apparatus for reconstructing print document using print preview function

(75) Inventor: Ki-Ja Lee, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/245,016

(22) Filed: Oct. 7, 2005

(30) Foreign Application Priority Data
Oct. 8, 2004 (KR) 2004-0080582

(51) Int. Cl. G03F 3/10

(52) U.S. Cl. 358/527

(57) ABSTRACT

A method for reconstructing a print document using a print preview function is provided. The method includes displaying a document to be printed using a print preview function, designating one or more areas to be printed in the displayed document, and reconstructing the designated areas into at least one page

### CROSS-REFERENCE TO RELATED APPLICATIONS

This application claims the benefit under 35 U.S.C. 119(a) of Korean Patent Application No. 10-2004-0080582, filed on Oct. 8, 2004, the entire disclosure of which is hereby incorporated by reference.

### BACKGROUND OF THE INVENTION

1. Field of the Invention

The present invention relates to an image forming apparatus. More particularly, the present invention relates to a method and apparatus for reconstructing a print document using a print preview function by which an area for printing is designated and the page can be reconstructed.

2. Description of the Related Art

In a conventional image forming apparatus, in order to edit or process a document to be printed, the document is edited or processed on an application program. In a print preview menu, the application program provides the document to be printed in read-only format, but editing or reconstruction of the document is not possible. That is, in a print preview state on a printer driver, it is not possible to designate an area of the document, reconstruct the documents corresponding to the designated area, and output the same. Thus, a user has to edit the original document on the application program to reconstruct the document into a variety of forms, which is inconvenient.

Accordingly, there is a need for an improved method and apparatus for reconstructing a print document using a print preview function to selectively print a designated area, without editing the original document.

### SUMMARY OF THE INVENTION

An aspect of the present invention is to address at least the above problems and/or disadvantages and to provide at least the advantages described below. Accordingly, an aspect of the present invention is to provide a method and apparatus for reconstructing a print document using a print preview function by which a particular area can be selectively printed by designating an area for printing in the original document and a page can be reconstructed into a variety of forms, without editing the original document.

According to an aspect of the present invention, a method for reconstructing a print document using a print preview function comprises the steps of displaying a document to be printed using a print preview function, designating one or more areas to be printed in the displayed document, and reconstructing the designated areas into at least one page.

In designating the areas to be printed, the one or more areas to be printed are designated in a plurality of pages which constitute the displayed print document. In designating the areas to be printed, the areas to be printed are designated in each page constituting the print document. In the step of designating of the one or more areas to be printed, the designation of the areas to be printed are made sing an input device such as a mouse and/or a keyboard.

The step of designating of the areas to be printed further comprises obtaining a coordinate value in the designated area and, in the step of reconstructing the designated areas, the designated areas are reconstructed into at least one page using the coordinate value.

The reconstructing of the designated areas is performed by selecting a reconstruction menu and the reconstruction menu comprises at least one a menu entitled “Original Document Position” to make the designated areas printed at the same position on the same page of the original document, a menu entitled “Auto” to print the designated areas by being continuously connected, and a menu entitled “Edition” to make a particular designated area to be printed at a particular position.

The method further comprises converting a reconstructed print document to printable data and transmitting the converted data to an image forming apparatus.

The steps of displaying the document to be printed, the designating of the areas to be printed, and reconstructing of the designated areas are implemented by, for example, a driver or an application program.

According to another aspect of the present invention, an apparatus for reconstructing a print document using a print preview function comprises a display portion displaying a document to be printed prior to printing using a print preview function, a print area designation portion designating one or more areas to be printed in the document displayed by the display portion, and a page reconstruction portion reconstructing the designated areas into at least one page.

In designating the areas to be printed by the print area designation portion, the areas to be printed are designated in a plurality of pages constituting the print document, and the areas are to be printed are configured to be designated on each page of the plurality of pages constituting the print document. The designating of areas to be printed by the print area designation portion is performed using an input device including a mouse and a keyboard.

The apparatus further comprises a coordinate value obtainment portion obtaining a coordinate value of the area designated by the print area designation portion in which the page reconstruction portion reconstructs the designated areas into at least one page using the coordinate value obtained by the coordinate value obtainment portion. The page reconstruction portion comprises a reconstruction menu and the reconstruction menu comprises at least one of a menu entitled “Original Document Position” to make the designated areas printed at the same position on the same page of the original document, a menu entitled “Auto” to print the designated areas by being continuously connected, and a menu entitled “Edition” to make a particular designated area to be printed at a particular position.

The apparatus further comprises a data conversion/transmission portion converting a reconstructed print document to printable data and transmitting the converted data to an image forming apparatus.

Other objects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other objects, features, and advantages of certain embodiments of the present invention will be more apparent from the following description taken in conjunction with the accompanying drawings, in which:

FIG. 1 is a block diagram illustrating a configuration of an apparatus which reconstructs a print document using a print preview function according to an embodiment of the present invention;

FIG. 2 is a flow chart which explains a method of reconstructing a print document using a print preview function according to an embodiment of the present invention;

FIG. 3 is a flow chart which explains a method of reconstructing a print document using a print preview function according to another embodiment of the present invention;

FIG. 4 is a view illustrating the original document displayed in a print preview mode;

FIG. 5 is a view illustrating the designation of areas of each page for printing by a user;

FIG. 6 is a view illustrating a full view of the designated print area;

FIG. 7 is a view illustrating a final print document displayed in a print preview mode;

FIG. 8A is a view illustrating a reconstructed page when a menu titled “Original Document Position” of the page reconstruction menus is selected;

FIG. 8B is a view illustrating a reconstructed page when a menu “Auto” of the page reconstruction menus is selected; and

FIG. 8C is a view illustrating a reconstructed page when a menu “Edition” of page reconstruction menus is selected.

Throughout the drawings, the same drawing reference numerals will be understood to refer to the same elements, features, and structures.

### DETAILED DESCRIPTION OF EXEMPLARY EMBODIMENTS

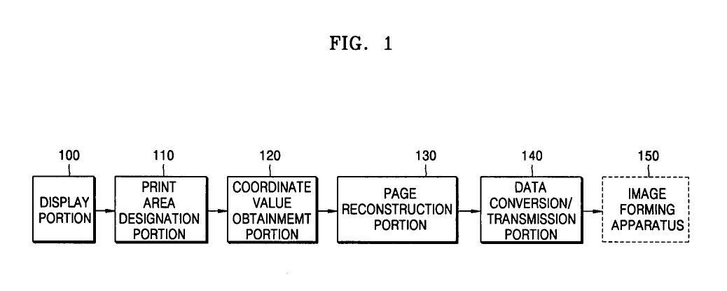

The matters defined in the description such as a detailed construction and elements are provided to assist in a comprehensive understanding of the exemplary embodiments of the invention. Accordingly, those of ordinary skill in the art will recognize that various changes and modifications of the embodiments described herein can be made without departing from the scope and spirit of the invention. Also, descriptions of well-known functions and constructions are omitted for clarity and conciseness. Referring to FIG. 1, an apparatus for reconstructing a print document using a print preview function according to an embodiment of the present invention includes a display portion 100, a print area designation portion 110, and a page reconstruction portion 130. The apparatus further comprises a coordinate value obtainment portion 120 and a data conversion/transmission portion 140.

The display portion 100 displays a document to be printed using a print preview function prior to printing. The print area designation portion 110 designates at least one area to be printed in the document displayed on the display portion 100. In the designation of the print area by the print area designation portion 110, the print area can be designated from a plurality of pages and different areas of each page to constitute the print document by using a mouse or a keyboard.

The coordinate value obtainment portion 120 obtains a coordinate value of the print area designated by the print area designation portion 110. The page reconstruction portion 130 reconstructs the designated print areas into at least one page using the coordinate values obtained from the coordinate value obtainment portion 120 and the data in the designated print area. The data conversion/transmission portion 140 converts the reconstructed print document into a printable data, for example, page description language (PDL) data, and transmits the printable data to an image forming apparatus 150.

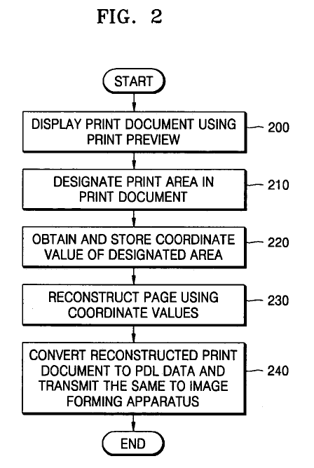

FIG. 2 is a flow chart which explains a method of reconstructing a print document using a print preview function according to an embodiment of the present invention. Referring to FIG. 2, a document to be printed is displayed using a print preview function (Step 200). At least one area to be printed of the displayed document is designated (Step 210). A print area can be designated across a plurality of pages and a plurality of print areas can be designated on each page to constitute the print document. The designation of the print area can be relatively easily performed using an input device such as a mouse or keyboard.

A coordinate value of each designated print area is obtained (Step 220). The designated print areas are reconstructed into at least one page using the obtained coordinate values (Step 230). The reconstructed print document is converted to printable data, for example, Page Description Language (PDL) data, and transmitted to the image forming apparatus (Step 240).

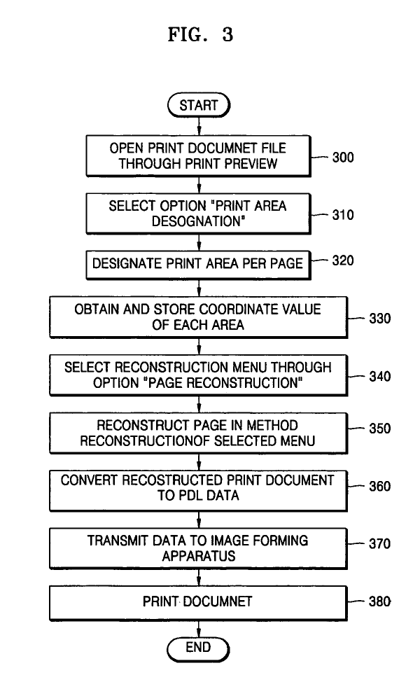

FIG. 3 is a flow chart which explains a method and the operation of the apparatus for reconstructing a print document using a print preview function according to another embodiment of the present invention.

The apparatus provides “Print Area Designation” and “Page Reconstruction” functions as options. The “Print Area Designation” function enables designation of an area across a plurality of pages using a mouse or a keyboard. Also, a plurality of print areas can be designated on each page. The “Page Reconstruction” function enables reconstruction of the designated print areas on a page and provides three menus for the reconstruction method. The menus may be, for example, “Original Document Position,” “Auto,” and “Edition”, but the exemplary embodiments of the present invention are not limited to these menus. The “Original Document Position” menu enables the designated print areas to be printed at the same positions as in the original document. The “Auto” menu enables the designated print areas to be printed by being continuously connected. The “Edition’ menu enables a user to designate a particular print area at a particular position.

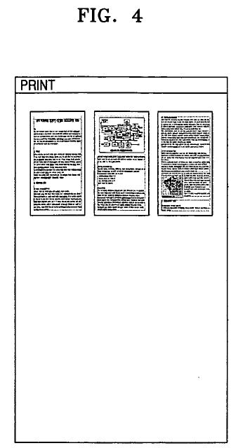

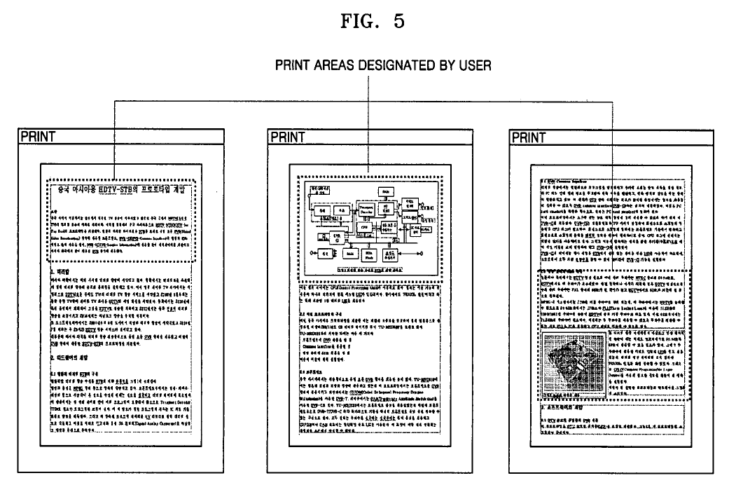

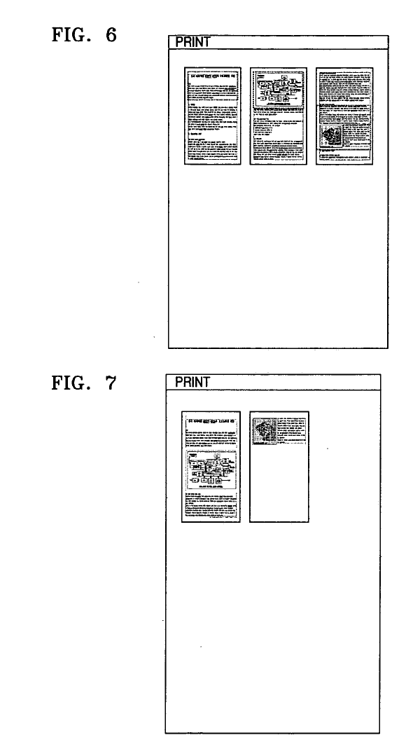

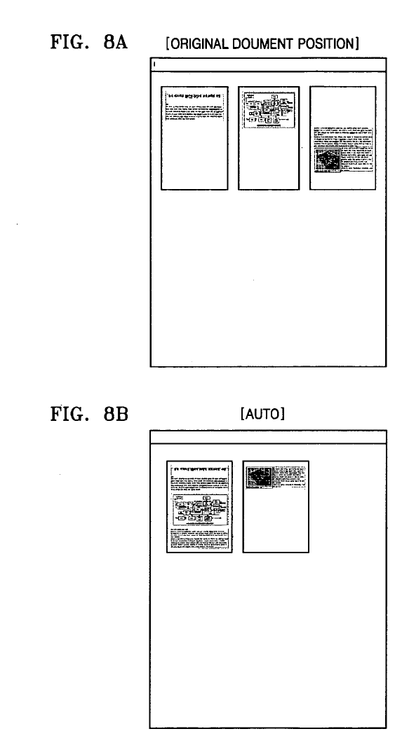

In detail, a print document file is opened using a print preview function of the display portion 100 (Step 300). FIG. 4 shows the original document displayed in a print preview mode. Next, a user selects a “Print Area Designation” option to print a particular print area in the document file without editing the document file (Step 310). A print area is designated on each page using a mouse or a keyboard through the print area designation portion 110 (Step 320). FIG. 5 is a view illustrating the designation of areas for printing on each page by a user. FIG. 6 is a view illustrating a full view of the designated print area. A coordinate value of each designated print area is obtained through the coordinate value obtainment portion 120 and the stored coordinate value is stored (Step 330). A page is reconstructed by the page reconstruction portion 130 using the stored coordinate value and data in the designated print area. The page reconstruction is performed by selecting a page reconstruction menu through the “Page Reconstruction” option (Step 340). When the page reconstruction menu is selected, the page is reconstructed in the method according to the selected reconstruction menu (Step 350). FIG. 7 is a view illustrating a final print document displayed in a print preview mode.

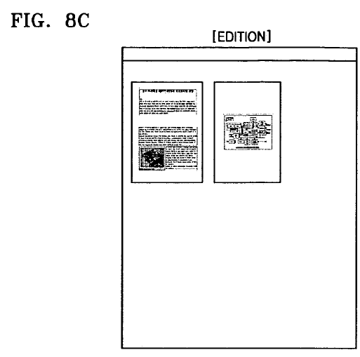

The page reconstruction menu includes the original document position, auto, and edition menus as described above. FIG. 8A is a view illustrating a reconstructed page when a menu “Original Document Position” of the page reconstruction menus is selected. FIG. 8B is a view illustrating a reconstructed page when a menu “Auto” of the page reconstruction menus is selected. FIG. 8C is a view illustrating a reconstructed page when a menu “Edition” of page reconstruction menus is selected. The print document can include text, images, and graphics.

When the page is reconstructed, a print document formed of the reconstructed pages is converted to PDL (page description language) data such as PCL or PS by the data conversion/transmission portion 140 (Step 360), transmitted to the image forming apparatus (Step 370), and printed as a document that the user desires (Step 380).

The method and apparatus which reconstructs a print document using a print preview function according to an embodiment of the present invention can be implemented through a driver or an application program.

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion.

As described above, according to the method and apparatus for reconstructing a print document using a print preview function according to the present invention, the user can selectively print a particular area only by designating a print area in the original document without editing the original document. Also, the user can print a variety of patterns by using various options such as “Original Document Position”, “Auto”, and “Edition” as a method to reconstruct a print page using a plurality of areas designated as the print area.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A method for reconstructing a print document using a print preview function, the method comprising the steps of:
displaying a document to be printed using a print preview function;
designating one or more areas to be printed in the displayed document; and
reconstructing the designated areas into at least one page.

2. The method as claimed in claim 1, wherein in the step of designating one or more areas to be printed, the areas to be printed are designated in a plurality of pages which constitute the displayed print document.

3. The method as claimed in claim 1, wherein in the step of designating one or more areas to be printed, the areas to be printed are designated in each page of a plurality of pages which constitute the displayed print document.

4. The method as claimed in claim 1, wherein in the step of designating one or more areas to be printed, the designation of the areas to be printed are made using an input device.

5. The method as claimed in claim 4, wherein the input device is a mouse.

6. The method as claimed in claim 4, wherein the input device is a keyboard.

7. The method as claimed in claim 1, wherein the step of designating one or more areas to be printed further comprises obtaining a coordinate value in the designated area, and the step of reconstructing of the designated areas, the designated areas are reconstructed into at least one page using the coordinate value.

8. The method as claimed in claim 1, wherein the reconstructing of the designated areas is performed by selecting a reconstruction menu and the reconstruction menu comprises at least one a menu entitled “Original Document Position” to make the designated areas printed at the same position on the same page of the original document, a menu entitled “Auto” to print the designated areas by being continuously connected, and a menu entitled “Edition” to make a particular designated area to be printed at a particular position.

7. The method as claimed in claim 1, further comprising the step of converting a reconstructed print document to printable data and transmitting the converted data to an image forming apparatus.

8. The method as claimed in 7, further comprising the step of converting a reconstructed print document to printable data and transmitting the converted data to an image forming apparatus.

9. The method as claimed in claim 1, wherein the steps of displaying the document to be printed, designating one or more areas to be printed, and reconstructing of the designated areas are implemented by a driver.

10. The method as claimed in claim 1, wherein the steps of displaying the document to be printed, designating one or more areas to be printed, and reconstructing of the designated areas are implemented by an application program.

11. The method as claimed in claim 5, wherein the displaying of a document to be printed, the designating of the areas to be printed, and reconstructing of the designated areas are implemented by a driver.

12. The method as claimed in claim 5, wherein the displaying of a document to be printed, the designating of the areas to be printed, and reconstructing of the designated areas are implemented by an application program.

13. An apparatus for reconstructing a print document using a print preview function, the apparatus comprising:
a display portion displaying a document to be printed prior to printing using a print preview function;
a print area designation portion designating one or more areas to be printed in the document displayed by the display portion; and
a page reconstruction portion reconstructing the designated areas into at least one page.

14. The apparatus as claimed in claim 13, wherein in the designating of the areas to be printed by the print area designation portion, the areas to be printed are designated in a plurality of pages constituting the print document, and the areas are to be printed are configured to be designated on each page of the plurality of pages constituting the print document.

15. The apparatus as claimed in claim 13, wherein the designating of the areas to be printed by the print area designation portion is performed using an input device including a mouse and a keyboard.

16. The apparatus as claimed in claim 15, wherein the input device is a mouse.

17. The apparatus as claimed in claim 15, wherein the input device is a keyboard.

18. The apparatus as claimed in claim 13, further comprising a coordinate value obtainment portion obtaining a coordinate value of the area designated by the print area designation portion, and
wherein the page reconstruction portion reconstructs the designated areas into at least one page using the coordinate value obtained by the coordinate value obtainment portion.

19. The apparatus as claimed in claim 13, wherein the page reconstruction portion comprises a reconstruction menu and the reconstruction menu comprises at least one menu entitled “Original Document Position” to make the designated areas printed at the same position on the same page of the original document, at least one menu entitled “Auto” to print the designated areas by being continuously connected, and at least one menu entitled “Edition” to make a particular designated area to be printed at a particular position.

20. The apparatus as claimed in claim 13, further comprising a data conversion/transmission portion converting a reconstructed print document to printable data and transmitting the converted data to an image forming apparatus.
